(19) United States
(12) Patent Application Publication
(10) Pub. No.: US 2006/0099828 A1
(43) Pub. Date: May 11, 2006

(54) SEMICONDUCTOR PROCESS AND PHOTORESIST COATING PROCESS

(76) Inventors: JUN-YIH YU, HSINCHU (TW); TIEN-CHU YANG, HSINCHU (TW); CHA0-LUNG LO, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,428

(22) Filed: Nov. 10, 2004

(51) Int. Cl. H01L 21/31

(52) U.S. Cl. 438/782

(57) ABSTRACT

A semiconductor process is disclosed, wherein before photoresist is coated on a substrate, a chemical is applied to dampen the substrate. Further, the chemical is applied on the substrate while the substrate is kept in a spinning state. In addition, a photoresist coating process is also provided. Wherein, a substrate is spun at a first speed. Then, a chemical is applied to dampen the surface of the spinning substrate. Next, the photoresist is coated on the surface of the substrate. The present invention can prevent defects in the formed photoresist layer during the coating process and therefore enhance the yield of the subsequent semiconductor process.

### BACKGROUND OF THE INVENTION

1Field of the Invention

The present invention relates to a semiconductor process and a photoresist-coating process, and more particularly, to a semiconductor process and a photoresist-coating process that keep the substrate in a spinning state before coating photoresist in order to prevent defects therein.

2Description of the Related Art

Photolithography is a vital process in the semiconductor manufacturing technology. It has been broadly applied in the process, for example, in patterning various film layers and in ion implantation.

A photolithographic process comprises the steps of photoresist coating, exposure and film development. Wherein, photoresist coating is an essential part in the photolithographic process. The prior photoresist-coating method starts by placing a substrate on the table of the spinner. The substrate is sucked on the table by proper vacuum degree provided through the axis of the spinner. The photoresist is then applied on the substrate. When the spinner starts spinning the substrate, the centrifugal force enables the photoresist to be spun over the substrate and a photoresist layer is thus formed.

After the formation of the photoresist layer, a baking process follows, wherein the solvent is removed from the photoresist layer. It should be noted that the formed photoresist layer in the conventional photoresist-coating process tends to have defects. These defects can be, for example, gaps or cracks in the photoresist layer. These defects have great consequence on the subsequent exposure and film development process, and may cause misalignment during the photolithographic process and therefore destroy the integrity of the photolithographic pattern. They may even impair the reliabilities and yields of the semiconductor devices. In particular, when the sizes of semiconductor devices shrink to deep sub-micron dimensions in which 193-nm photolithographic process should be applied, the defects become even more obvious.

### SUMMARY OF THE INVENTION

Accordingly, the present invention is directed to a semiconductor process in which a new photoresist-coating method is applied to avoid the defects during a photoresist coating process that may trouble subsequent process.

The present invention is also directed to a photoresist-coating method to avoid the defects formed during a photoresist-coating process such that a desired photoresist layer can be formed and the reliability and yield of the semiconductor devices can be improved.

The present invention provides a semiconductor process. The process starts by dampening a substrate with a chemical before coating photoresist over the substrate, wherein the substrate is kept in a spinning state while the chemical is applied.

According to one embodiment of the semiconductor process in the present invention, when the chemical is applied on the substrate, the substrate starts spinning.

According to one embodiment of the semiconductor process in the present invention, before the chemical is applied on the substrate, the substrate starts spinning.

According to one embodiment of the semiconductor process in the present invention, a time to apply the chemical is more than about 3 seconds. More preferably, the semiconductor process further comprises the step of spinning the chemical over the substrate within a timeframe from about 0.6 second to about 2 seconds.

According to one embodiment of the semiconductor process in the present invention, the said chemical comprises edge backside rinse (EBR).

The present invention also provides a photoresist-coating method. The photoresist-coating method starts by spinning a substrate at a first speed. Next, a chemical is applied on a surface of the spinning substrate to dampen the surface. Then, photoresist is coated over the surface of the substrate.

According to one embodiment of the photoresist-coating method in the present invention, a chemical is applied on the surface of the substrate while the substrate starts spinning.

According to one embodiment of the photoresist-coating method in the present invention, a chemical is applied on the surface of the substrate after the substrate starts spinning.

According to one embodiment of the photoresist-coating method in the present invention, the said first speed is from about 300 rpm to about 1,500 rpm.

According to one embodiment of the photoresist-coating method in the present invention, the method of coating the photoresist over the surface of the substrate comprises the step of spinning the substrate at a second speed and then applying the photoresist on the surface of the substrate. Wherein, the second speed is higher than the first speed.

Accordingly, in the present invention, a chemical is applied to dampen a substrate while the substrate is kept in a spinning state, before photoresist-coating process. The step can improve the effect of the subsequent photoresist-coating process and avoid possible defects formed during the process. Further, in the present invention, the substrate is kept spinning before the photoresist—is coated thereon, so the gaps or cracks in the formed photoresist layer can be avoided. In short, the present invention can reduce the defects formed during a photoresist-coating process and eventually improve the reliability and yield of semiconductor devices.

The above and other features of the present invention will be better understood from the following detailed description of the embodiments of the invention that is provided in combination with the accompanying drawings.

### BRIEF DESCRIPTION OF THE DRAWINGS

FIGS. 1A-1C are schematic cross-sectional configurations showing a photoresist-coating method according to one embodiment of the present invention.

FIG. 2 is a flowchart showing a photoresist-coating method according to one embodiment of the present invention.

### DESCRIPTION OF THE EMBODIMENTS

In semiconductor process, the photoresist technology has been applied broadly. As a result, defects in the formed photoresist layer will have great consequence on the subsequent process and even the integrity of semiconductor devices.

In the present invention, a chemical is applied to dampen a substrate before photoresist is coated on the substrate. Further, when the chemical is applied on the substrate, the substrate is kept in a spinning state. What follows is the description of a photoresist-coating process according to an embodiment of the present invention.

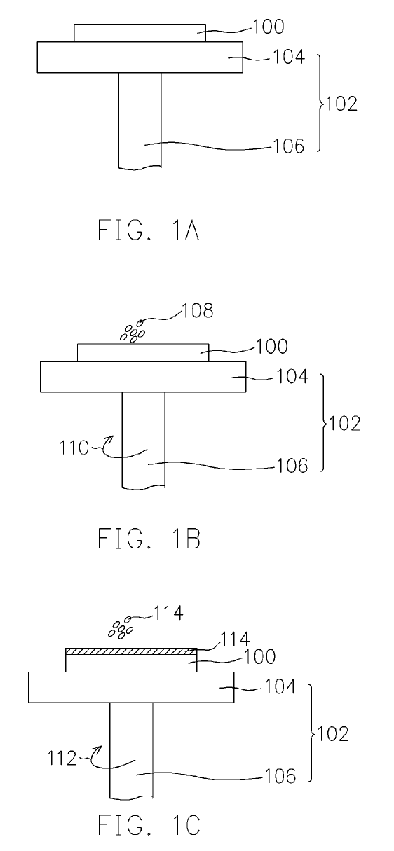

FIGS. 1A-1C are schematic cross-sectional configurations showing a photoresist-coating method according to one embodiment of the present invention.

As shown in FIG. 1A, a substrate 100 is placed on a plate 104 of a spinner 102. The substrate 100 is sucked on the plate 104 by a proper amount of vacuum provided through the axis 106 of the spinner 102.

Next, with reference to FIG. 1B, a chemical 108 is applied to dampen the substrate 100. When the chemical 108 is applied on the substrate 100, the substrate 100 is kept in a spinning state. Wherein, the spinning speed of the substrate 100 can be from about 300 rpm to about 1,500 rpm. The time of applying the chemical 108 can be more than about 3 seconds. The chemical 108 can be the edge backside rinse (EBR).

In addition, in the photoresist-coating method of the present invention, the chemical 108 can be applied on the surface of the substrate 100 while the substrate 100 starts spinning. Further, in the present invention, the chemical 108 can be applied on the surface of the substrate 100 after the substrate starts spinning.

In one embodiment of the present invention, after the step of applying the chemical 108 on the surface of the substrate 100, a spinning step follows, wherein the chemical 108 is spun over the surface of the substrate 100. The timeframe of the spinning stepcan be from about 0.6 seconds to about 2 seconds.

Before the photoresist-coating process, the chemical is applied to dampen the substrate while the substrate is kept spinning, whereby the defects in the formed photoresist layer can be avoided. In addition, the method of dampening the substrate with a chemical while the substrate is kept spinning can not only be applied to photoresist coating, but also to other spin-coating methods in the semiconductor process.

Please refer to FIG. 1C, a photoresist 114 is coated on the surface of the substrate 100. The method of coating the photoresist 114 on the surface of the substrate 100 starts by spinning the substrate 100 at a spinning speed. The photoresist 114 is then applied to the surface of the substrate 100 to form the photoresist layer 114. Wherein, the spinning speed of the substrate 100 herein is faster than that while the chemical 108 is applied on substrate 100. In this step, the spinning speed of the substrate 100 can be about 1,500 rpm.

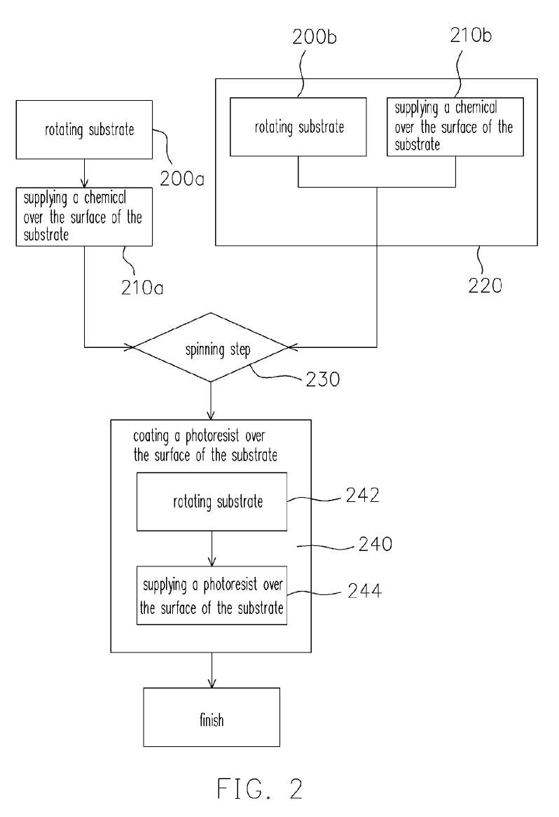

More specifically, the photoresist-coating method of the present invention comprises multiple steps. FIG. 2 is a flowchart showing a photoresist-coating method according to another embodiment of the present invention.

As shown in FIG. 2, the method may start with the step 200a, wherein the substrate is kept spinning. Then, in step 210a, the chemical is applied on the surface of the substrate. In another embodiment, the step 200b of spinning the substrate and the step 210b of applying the chemical can be performed simultaneously as shown in step 220.

In addition, after the foregoing steps, step 230 may be performed wherein the chemical is spun over the substrate evenly.

Next, in step 240, the photoresist is coated over the surface of the substrate. The step 240 comprises spinning the substrate (i.e. step 242), and applying the photoresist over the surface of the substrate (i.e. step 244). After step 240, the photoresist-coating process of the present invention is complete.

Accordingly, in the present invention, the substrate starts spinning before the photoresist is coated. Therefore, the method can avoid gaps or cracks in the formed photoresist layer that may trouble the subsequent process and therefore improves the reliability and yield of the semiconductor devices. In addition, in the present invention, a chemical is applied to dampen the substrate while the substrate is kept spinning, before the photoresist-coating process. This method can enhance a desired photoresist-coating and reduce the possible defects in the formed photoresist layer.

To sum up, the present invention has the following advantages:

1. In the present invention, a chemical is applied to dampen a substrate while the substrate is kept in a spinning state, before the photoresist-coating process. The method can prevent defects in the formed photoresist layer during the coating process.

2. The semiconductor manufacturing method in the present invention can prevent gaps or cracks in the formed photoresist layer that may affect the subsequent process and therefore the reliability and yield of semiconductor devices can be improved.

3. The semiconductor manufacturing method in the present invention can be applied not only to photoresist coating, but also to other spin-coating methods in the semiconductor process.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A semiconductor process, wherein a chemical is applied onto a substrate before photoresist is coated thereon, the process being characterized by a spinning state of the substrate while the chemical is applied thereon, wherein a time of applying the chemical is more than 3 seconds.

2. The semiconductor process of claim 1, wherein while the chemical is applied onto the substrate, the substrate starts spinning.

3. The semiconductor process of claim 1, wherein before the chemical is applied onto the substrate, the substrate starts spinning.

4. (canceled)

5. The semiconductor process of claim 1, furtler comprising the step of spinning the chemical on the surface of the substrate after the chemical is applied thereon.

6. The semiconductor process of claim 5, wherein a timeframe of spinning the chemical is from about 0.6 seconds to about 2 seconds.

7. The semiconductor process of claim 1, wherein the chemical comprises edge backside rinse (EBR).

8. A photoresist-coating method, comprising:
spinning a substrate at a first speed;
applying a chemical over a surface of the spinning substrate to dampen the surface thereon, wherein a time of applying the chemical is more than 3 seconds; and
coating photoresist over the surface of the substrate.

9. The photoresist-coating method of claim 8, wherein while the substrate starts spinning, the chemical is applied to the surface of the substrate.

10. The photoresist-coating method of claim 8, wherein after the substrate starts spinning, the chemical is applied to the surface of the substrate.

11. The photoresist-coating method of claim 8, wherein the first speed Is from about 300 rpm to about 1,500 rpm.

12. The photoresist-coating method of claim 8, wherein the step of coating pliotoresist on the surface of the substrate comprises:
spinning the substrate at a second speed; and
applying photoresist over the surface of the substrate.

13. The photoresist-coating method of claim 12, wherein the second speed is faster than the first speed.

14. The photoresist-coating method of claim 8, wherein the chemical comprises edge backside rinse (EBR).

15. (canceled)

16. The photoresist-coating method of claim 8, further comprising the step of spinning the chemical over the surface of the substrate after the chemical is applied thereon.

17. The photoresist-coating method of claim 16, wherein atimeframe of spinning the chemical is from about 0.6 second to about 2 seconds.
